(19) United States
(12) Patent Application Publication
(10) Pub. No.: US 2004/0025791 A1
(43) Pub. Date: Feb. 12, 2004

(54) Etch chamber with dual frequency biasing sources and a single frequency plasma generating source

(75) Inventors: Jin-Yuan Chen, Union City, CA (US); Frank F. Hooshdaran, Pleasanton, CA (US); Dragan V. Podlesnik, Palo Alto, CA (US)

Correspondence Address: Patent Counsel, Applied Materials, Inc., 3050 Bowers Avenue, P.O. Box 450A, Santa Clara, CA, 95052, US

(73) Assignee: Applied Materials, Inc.

(21) Appl. No.: 10/342,575

(22) Filed: Jan. 14, 2003

Related U.S. Application Data
(60) Provisional application No. 60/402,291, filed on Aug. 9, 2002.

(51) Int. Cl. C23C 16/00

(52) U.S. Cl. 118/728

(57) ABSTRACT

A method and apparatus for selectively controlling a plasma in a processing chamber during wafer processing. The method includes providing process gasses into the chamber over a wafer to be processed, and providing high frequency RF power to a plasma generating element and igniting the process gases into the plasma. Modulated RF power is coupled to a biasing element, and wafer processing is performed according to a particular processing recipe. The apparatus includes a biasing element disposed in the chamber and adapted to support a wafer, and a plasma generating element disposed over the biasing element and wafer. A first power source is coupled to the plasma generating element, and a second power source is coupled to the biasing element. A third power source is coupled to the biasing element, wherein the second and third power sources provide a modulated signal to the biasing element.

### CROSS REFERENCE TO RELATED APPLICATION

This patent application claims the benefit of U.S. Provisional Application, serial No. 60/402,291, filed Aug. 9, 2002, the contents of which are incorporated by reference herein.

### FIELD OF THE INVENTION

Embodiments of the invention generally relate to semiconductor wafer processing, and more particularly, to etch and plasma related integrated circuit manufacturing processes and related hardware.

### BACKGROUND OF THE INVENTION

Semiconductor fabrication wafer process chambers employing plasma to perform etching and deposition processes utilize various techniques to control plasma density and acceleration of plasma components. For example, magnetically-enhanced plasma chambers employ magnetic fields to increase the density of charged particles in the plasma, thereby further increasing the rate of plasma-enhanced deposition and etching processes. Increasing the process rate is highly advantageous because the cost of fabricating semiconductor devices is proportional to the time required for fabrication.

During a plasma-enhanced process, such as a reactive ion etch process, material on the wafer is removed in specific areas to subsequently form the components/features of the devices (e.g., transistors, capacitors, conductive lines, vias, and the like) on the wafer. A mask is formed over areas of the wafer that are to be protected from the etching process. Uniformity of the etching rate across the wafer during the entire etch process is very important for ensuring that features are etched with precision at any location on the wafer. The uniformity of the etching process is related to the ability to control the plasma throughout the etch process. For example, U.S. Pat. No. 6,354,240 includes disposing magnets around the reactor chamber to provide a magnetic confinement to sustain a high plasma density in a low pressure environment.

However, during “deep trench etching”, the wafer may be exposed to the etchants for a long duration. During these long etching processes, the etch mask can be completely etched from the wafer surface to leave the surface unprotected. That is, the deep trench processes are limited by the selectivity between the material of the protective mask and the material to be etched, where the higher the selectivity, the deeper the trench may be etched.

Therefore, there is a need in the art for increasing the selectivity during deep trench etching, such that a sufficient portion of the masking material remains to cover areas of the wafer to be protected until the etch process is complete.

### SUMMARY OF THE INVENTION

The present invention provides an etch chamber that is driven with three RF frequencies: one frequency for establishing and maintaining a plasma, and two frequencies for biasing a biasing element (e.g., wafer pedestal). Such triple frequency use provides improved plasma control that increases the process window for an etch process. Enhancing control of plasma density and ion energy improves the coverage of more etching applications and provides a wider window of processing.

In particular, the present invention provides an apparatus for controlling a plasma in a chamber during wafer processing. The apparatus comprises a biasing element disposed in the chamber and adapted to support a wafer, and a plasma generating element disposed proximate the biasing element. A plasma generating (top) power source is coupled to the plasma generating element, and a bottom (biasing) power source is coupled to the biasing element to provide a modulated signal that modulates the plasma.

A method for selectively controlling a plasma in the processing chamber during wafer processing comprises providing process gasses into the chamber over a wafer to be processed, and providing high frequency RF power to the plasma generating element, which ignites the process gases into the plasma. A modulated RF power signal is provided to the biasing element, and wafer processing is performed according to a particular processing recipe.

### BRIEF DESCRIPTION OF THE DRAWINGS

So that the manner in which the above recited features of the invention are attained can be understood in detail, a more particular description of the invention, briefly summarized above, may be had by reference to the embodiments thereof, which are illustrated in the appended drawings. It is to be noted, however, that the appended drawings illustrate only typical embodiments of this invention, and are therefore, not to be considered limiting of its scope, for the invention may admit to other equally effective embodiments.

FIG. 1 depicts a cross-sectional view of a first embodiment of a dual frequency bias plasma chamber system;

FIG. 2 depicts a top cross-sectional view of the plasma chamber system of FIG. 1;

FIG. 3 depicts a flow diagram of a method for selectively controlling a plasma during wafer processing;

FIG. 4 depicts a cross-sectional view of a second embodiment of a dual frequency bias plasma chamber system; and

FIGS. 5A-5D depict graphs of exemplary RF waveforms used in the present invention.

To facilitate understanding, identical reference numerals have been used, where possible, to designate identical elements that are common to the figures.

### DETAILED DESCRIPTION

One application of the present invention provides an apparatus for performing high aspect ratio deep trench etching. In particular, a processing chamber is equipped with dual frequency biasing sources and a single frequency plasma generating source. A wafer to be processed is secured on a support pedestal in the chamber. The single frequency plasma generating source is coupled to a plasma generating element disposed over the wafer to be processed, while a pair of biasing sources having different frequencies are coupled to the support pedestal, such that the support pedestal serves as a biasing element.

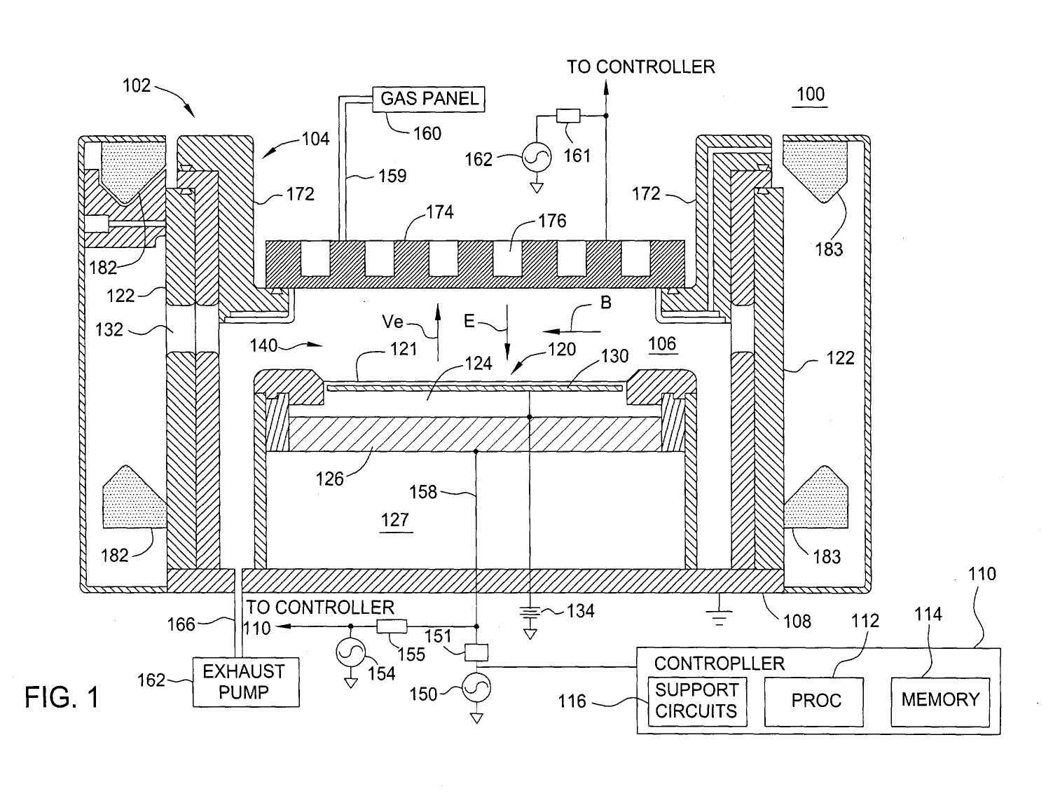

FIG. 1 depicts a cross sectional view of a first embodiment of a dual frequency bias plasma chamber system 100 of the present invention. Specifically, FIG. 1 depicts an illustrative chamber system (system) 100 that can be used in high aspect ratio trench formation. The system 100 generally comprises a chamber body 102 and a lid assembly 104 that defines an evacuable chamber 106 for performing substrate processing. In one embodiment, the system 100 is an MxP type etch system available from Applied Materials, Inc. of Santa Clara, Calif. For a detailed understanding of an MxP type system, the reader is directed to U.S. Pat. No. 6,403,491, issued Jun. 11, 2002, the contents of which is incorporated by reference herein in its entirety. Further, other types of wafer processing systems are also contemplated, such as an eMAX type system, a PRODUCER e type system, HOT type system, and an ENABLER type system, among others, all of which are also available from Applied Materials, Inc. of Santa Clara, Calif.

The system 100 further comprises a gas panel 160 coupled to the chamber 106 via a plurality of gas lines 159 for providing processing gases, an exhaust stack 164 coupled to the chamber 106 via an exhaust passage 166 for maintaining a vacuum environment and exhausting undesirable gases and contaminants. Additionally, a controller 110 is coupled to the various components of the system 100 to facilitate control of the processes (e.g., deposition and etching processes) within the chamber 106.

The chamber body 102 includes at least one of sidewall 122 and a chamber bottom 108. In one embodiment, the at least one sidewall 122 has a polygon shaped (e.g., octagon or substantially rectangular) outside surface and an annular or cylindrical inner surface. Furthermore, at least one sidewall 122 may be electrically grounded. The chamber body 102 may be fabricated from a non-magnetic metal, such as anodized aluminum, and the like. The chamber body 102 contains a substrate entry port 132 that is selectively sealed by a slit valve (not shown) disposed in the processing platform.

A lid assembly 104 is disposed over the sidewalls 122 and defines a processing region 140 within the chamber 106. The lid assembly 104 generally includes a lid 172 and a plasma generating element (e.g., source or anode electrode) 174 mounted to the bottom of the lid 172. The lid 172 may be fabricated from a dielectric material such as aluminum oxide (Al₂O₃), or a non-magnetic metal such as anodized aluminum. The plasma generating element 174 is fabricated from a conductive material such as aluminum, stainless steel, and the like.

Further, the plasma generating element 174 is coupled to a high frequency RF power source 162 via a matching network 161. The high frequency power source (top power source) 162 provides RF power in a range between about 100 Watts to 7500 Watts, at a frequency in the range of about 40-180 MHz, and is used to ignite and maintain a plasma from a gas mixture in the chamber 106.

The plasma generating element 174 may be provided with perforations or slits 176 to serve as a gas diffuser. That is, the plasma generating element 174 may also serve as a showerhead, which provides processing gases that, when ignited, forms a plasma in the processing region 140. The processing gases, (e.g., CF₄, Argon (Ar), C₄F₈, C₄F₆, C₈F₄, CHF₃, Cl₂, HBr, NF₃, N₂, He, O₂ and/or combinations thereof) are provided to the plasma generating element/showerhead 174 from the external gas panel 160 via the gas conduit 159 coupled therebetween.

In another embodiment, a gas distribution ring (not shown) may be coupled to the lid assembly 104 to provide the processing gases into the chamber 106. The gas distribution ring typically comprises an annular ring made of aluminum or other suitable material having a plurality of ports formed therein for receiving nozzles that are in communication with the gas panel 160.

A substrate support pedestal 120 is disposed within the chamber 106 and seated on the chamber bottom 108. A substrate (i.e., wafer, not shown) undergoing wafer processing is secured on an upper surface 121 of the substrate support pedestal 120. The substrate support 120 may be a susceptor, a heater, ceramic body, or electrostatic chuck on which the substrate is placed during processing. The substrate support pedestal 120 is adapted to receive an RF bias signal, such that the substrate support pedestal serves as a biasing element (e.g., cathode electrode) with respect to the RF bias signal, as is discussed below in further detail.

In the embodiment of FIG. 1, the substrate support pedestal 120 comprises an electrostatic chuck 124 coupled to an upper surface of a cooling plate 126. The cooling plate 126 is then coupled to an upper surface of the pedestal base 127. The electrostatic chuck 124 may be fabricated from a dielectric material e.g., a ceramic such as aluminum nitride (AlN), silicon oxide (SiO), silicon nitride (SiN), sapphire, boron nitride, or it can be a plasma sprayed aluminum nitride, or aluminum oxide material on an anodized aluminum surface, or the like, and is generally shaped as a thin circular puck.

Furthermore, the electrostatic chuck 124 may be provided with one or more chucking electrodes 130. The chucking electrodes 130 are, for example, fabricated from a conductive material, (e.g., tungsten). The chucking electrodes 130 are disposed relatively close to the top surface of the electrostatic chuck 124. In this way, the chucking electrodes 130 provide the necessary electrostatic force to the backside of a wafer to retain (i.e., chuck) the wafer on the electrostatic chuck 124. The chucking electrodes 130 may be in any configuration such as a monopolar configuration, bipolar configuration, zoned chucking configuration, or any other configuration suitable to retain the wafer to the chuck 124. The chucking electrodes 130 are connected to a remote power source, i.e. a high voltage DC (HVDC) power supply 134, which provides a chucking voltage sufficient to secure the wafer to the chuck 124.

The cooling plate 126 assists in regulating the temperature of the electrostatic chuck 124. Specifically, the cooling plate 126 is fabricated from a material that is a high conductor of RF power, such as molybdenum, a zirconium alloy (e.g., Zr—Hf), a metal matrix composite (e.g., Al—Si—SiC), among others. Furthermore, the materials used to fabricate the cooling plate 126 are selected from a group of materials that will have a thermal expansion coefficient value close to the thermal expansion coefficient value of the electrostatic plate 124. The cooling plate 126 comprises channels (not shown) formed therein to circulate a coolant to reduce the thermally conducted heat radiated from the wafer and the electrostatic chuck 124.

Additional temperature control may be provided by a heating element embedded in the electrostatic chuck 124. Moreover, a backside gas delivery system (not shown) is provided, such that a gas (e.g., helium) is provided between grooves (not shown), which are formed in the top surface of the chuck 124, and the backside of the wafer.

As discussed above, the substrate support pedestal 120 also serves as a biasing electrode (e.g., cathode) for biasing the ionized gases towards the wafer during either a deposition or etching process. A first bias power supply 150 and a second bias power supply 154 are coupled in parallel between the substrate support pedestal 120 and ground via respective matching networks 151 and 155. In one embodiment, the grounded sidewalls 122 and the plasma generating element 174 together define the anode with respect to the biasing element (cathode) in the substrate support pedestal 120.

In particular, the first biasing power supply 150 provides RF power in the range of about 10 Watts to 7500 Watts (W), and at a frequency in the range of about 100 KHz to 6 MHz. The second biasing power supply 154 provides RF power in the range of about 10 W to 7500 W, at a frequency in the range of about 4 MHz to 60 MHz, and, for example, at a frequency of 13.56 MHz. As such, the signal from the first bias power supply 150 amplitude modulates the signal from the second bias power supply 154. For example, a 13.56 MHz signal from the second bias power supply 154 is amplitude modulated with a 2 MHz signal from the first biasing power supply 150. It is noted that one skilled in the art will appreciate that the power levels of the first and second biasing power supplies 150 and 154 are related to the size of the workpiece being processed. For example, a 300 mm wafer requires greater power consumption than a 200 mm wafer during processing.

In one embodiment, the chucking electrodes 130 may also function as the biasing element. In particular, the first and second bias power supplies 150 and 154 are coupled to the chucking electrode 130, such that the bias signal (e.g., modulated RF signal) is applied to the electrodes 130 to create a bias voltage. In another embodiment, the first and second bias power supplies 150 and 154 are coupled to the cooling plate 126, which thereby functions as a biasing element. Alternatively, the first and second bias power supplies 150 and 154 may be coupled to a base plate (not shown) disposed below the cooling plate 126, or to another anode placed within the chuck 124.

It is noted that the controller 110 may be utilized to control the bias power supplies 150 and 154, as well as control the high frequency RF power source 162. In particular, the controller 110 controls the power set points of the bias power supplies 150 and 154 to provide either the bias signal or the modulated signal. That is, the controller 110 may be used to control the low RF frequency bias signal (e.g., 2 MHz signal) provided by the first bias power supply 150, as well as control the intermediate RF frequency bias signal (e.g., 13.56 MHz signal) provided by the second bias power supply 154. Moreover, the controller 110 controls the set point of the high frequency RF signal from the high frequency RF power source 162. It is noted that a person skilled in the art will appreciate that the power levels set by the controller 110 for the power sources 150, 154, and 162 are related to the size of the wafer being processed (e.g., 200 millimeter (mm) and 300 mm wafers)

It is noted that the two bias input power signals from the bias power supplies 150 and 154 are not modulated until after the formation of the plasma. Specifically, the plasma acts as a non-linear device, such as a diode, so that the two bias power supplies 150 and 154 may be modulated in the plasma. The degree of modulation depends on the plasma condition, biasing signal power levels, and their respective frequencies.

Once the biasing signals are modulated in the plasma, the plasma density and acceleration may be changed in a controlled manner depending on the modulation scheme. During an etching process, the selectivity increases such that the protective mask (e.g., a photoresist mask) has a longer life that allows increased depth and aspect ratio when etching deep trenches (e.g., vias). The use of a modulated bias signal provides an increased process window for many etch processes.

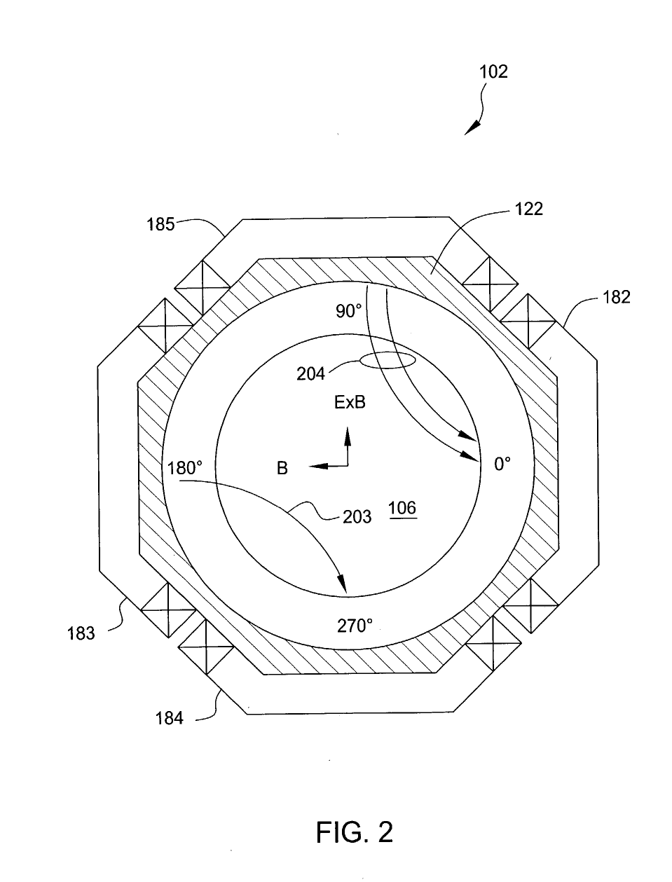

FIG. 2 depicts a top cross-sectional view of the plasma chamber system 100 of FIG. 1. In particular, FIG. 2 depicts an embodiment where the plasma chamber system 100 is magnetically enhanced using a DC magnetic field in the processing region 140 between the plasma generating element 174 and the biasing element 120. That is, the chamber (also referred to as a reactor) employs magnetic fields to increase the density of charged particles in the plasma, thereby further increasing the rate of the plasma enhanced fabrication process.

Typically, the direction of the magnetic field is traverse with respect to the longitudinal axis of the chamber 106, that is, traverse to an axis extending between the electrodes 120 and 174. Various arrangements of permanent magnets or electromagnets are conventionally used to provide such transverse magnetic field. One such arrangement is a first main pair of coils 182 and 183 disposed on opposite sides of the cylindrical chamber side wall 122, and a second main pair of coils 184 and 185 disposed on opposite sides of the cylindrical chamber side wall 122. Each pair of opposing main coils 182-185 are connected in series and in phase to a DC power supply (not shown), such that they produce transverse (adjacent) magnetic fields, which are additive in the region between the coil pairs. The traverse magnetic field is represented in FIGS. 1 and 2 by the vector “B” oriented along the negative X-axis. Variations on the magnetic fields may also be utilized, such as opposed magnetic fields as used in an etch MxP dielectric chamber, also available from Applied Materials Inc., of Santa Clara, Calif.

To facilitate control of the system 100 as described above, the controller 110 may be one of any form of general-purpose computer processor that can be used in an industrial setting for controlling various chambers and sub-processors. In general, the process controller 110 includes a central processing unit (CPU) 112 in electrical communication with a memory 114 and support circuits 116. The support circuits 116 include various buses, I/O circuitry, power supplies, clock circuits, cache, among other components.

The memory 114, or computer-readable medium, may be one or more of readily available memory such as random access memory (RAM) read only memory (ROM), floppy disk, hard disk, or any other form of digital storage that are locally and/or remotely connected. Software routines are stored in memory 114. The software routines, when executed by the CPU 112, cause the reactor to perform processes of the present invention. The software routines may also be stored and/or executed by a second CPU (not shown) that is remotely located from the hardware being controlled by the CPU 112.

The software routines are executed after the wafer is positioned on the support pedestal 120. The software routines, when executed by the CPU 112, transform the general-purpose computer into a specific purpose computer (controller) 110 that controls the chamber operations such that the etching process is performed in accordance with the method of the present invention.

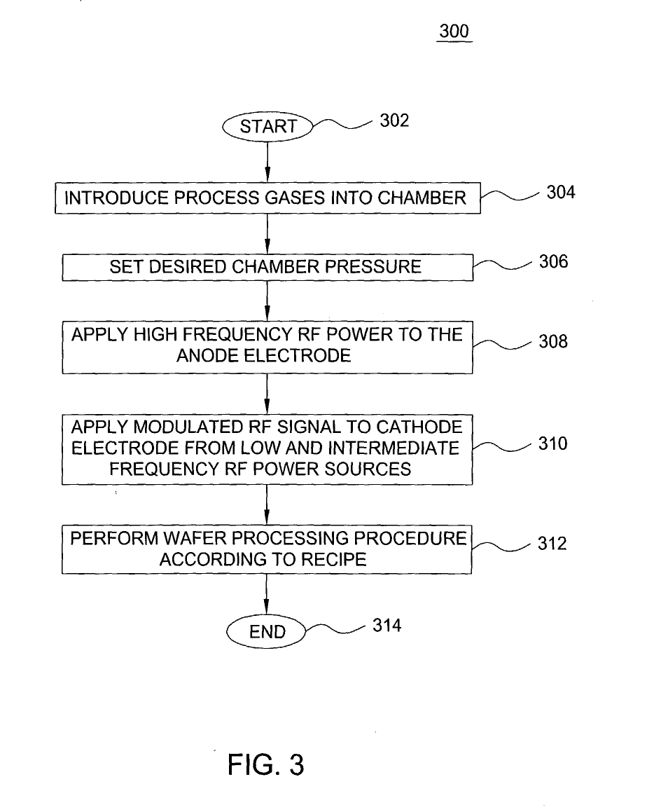

FIG. 3 depicts a flow diagram of a method 300 for selectively controlling a plasma during wafer processing. Specifically, the method 300 provides a technique for controlling plasma density and particle acceleration, which allows for greater depth and aspect ratios to be achieved on the wafer during deep trench etching.

The method 300 starts at step 302, where a substrate is loaded, moved into an appropriate processing position over the substrate support pedestal 106. At step 304, a process gas is introduced into the chamber 106 via the exemplary showerhead of FIG. 1 or at least one nozzle. The process gas may include Argon (Ar), CF₄, C₄F₈, C₄F₆, C₈F₄, CHF₃, Cl₂, HBr, NF₃, N₂, He, O₂ and/or combinations thereof, and are introduced into the chamber 106 at rates of between about 1 sccm to about 2000 sccm.

At step 306, the pressure in the chamber 106 is brought to a desired processing pressure by adjusting a pumping valve (not shown) to pump the gas into the chamber 106 at a desired pressure. In one operational aspect of generating plasma, the pressure may be between about 1 milliTorr and about 1000 milliTorr.

Plasma may be generated via application of the source power by the top power supply 162 between the plasma generating element 174 and ground (e.g., the chamber sidewalls and/or bias element. At step 308, the top power supply 162 applies the source power between about 100 Watts and about 7500 Watts, at a frequency of about 40 MHz to about 180 MHz, which ignites the process gas or gases introduced into the processing region 140 into a plasma. In particular, the gas mixture (e.g., Ar) is introduced into the processing region 140 of the chamber 106. Once the pressure in the chamber reaches a pressure setpoint, the gas is ignited by the RF signal provided by the RF power source 162 to form the plasma. The wafer is then chucked to the substrate support pedestal 120, and then the other processing gases are provided to the chamber 106. The method 300 proceeds to step 308.

At step 310, the bias power supplies 150 and 154 are activated and the biasing element 120 is biased with the modulated bias signal. Recall that the biasing element may be formed by coupling the bias power supplies 150 and 154 to the chucking electrode 130, the cooling plate 126, cathode base plate, among other components in the substrate support pedestal 120. It is noted that the order of steps 308 and 310 of method 300 should not be considered as limiting, but rather, may be performed alternately or simultaneously.

In particular, the intermediate RF bias power source 150 and low RF bias power source 154 are turned on, and the biasing element 120 is biased to between about 10 Watts and about 7500 Watts. Furthermore, the RF signal from the two bias power sources 150 and 154 provide a modulated signal, such that the intermediate frequency signal (e.g., 13.56 MHz) is modulated by the low frequency signal (e.g., 400 KHz to 2 MHz).

The intermediate frequency RF source (second biasing power supply) 154 provides a sufficient energy level to accelerate the ions towards the biasing element 120, such that the particles bombard the wafer during the etching process. Further, the low frequency RF bias source 150 provides a wide energy band that increases the plasma density near the wafer. By increasing the plasma density, more particles are available for bombarding the wafer. As such, the modulated RF waveform provided by the bias power supplies 150 and 154 provides additional control of the energy used to accelerate the ions, as well as control the plasma density in the processing region 140.

At step 312, the wafer processing procedure (e.g., deep trench etching) is performed according to a particular recipe. The operation of the plasma process may be monitored by a process analysis system (not shown) to determine when the wafer processing has reached an endpoint value and is complete. Once the processing recipe is completed, at step 314, the plasma generation may be terminated and the wafer removed from the processing chamber for further processing, where the method 300 ends.

In one exemplary embodiment, a deep trench having a width of about 14 micrometers (μm) and an aspect ratio of at least about 6:1 may be formed in a silicon wafer by providing the modulated waveform to the plasma during the etch step 312. In particular, process gases such as NF₃ (at a rate of 80 sccm) and HBr (at a rate of 400 sccm) are provided to the reactor chamber 106. The flow ratio of NF₃ to HBr is about 1:5. The pressure in the reaction chamber 106 is maintained at about 100 to 400 mTorr. The top power supply 162 applies the source power at about 3000 Watts at a frequency of about 60 MHz, which ignites the process gases in the processing region 140 into a plasma. The intermediate RF bias power source 150 is set to provide power in a range of about 2000 to 3000 Watts at a frequency of 13.56 MHz, while the low RF bias power source (e.g., first biasing power supply) 154 provides power in a range of about 2000 to 3000 Watts at a frequency of 2 MHz. The RF signal from the two bias power sources 150 and 154 provide a RF signal modulated by about 10 to 80 percent.

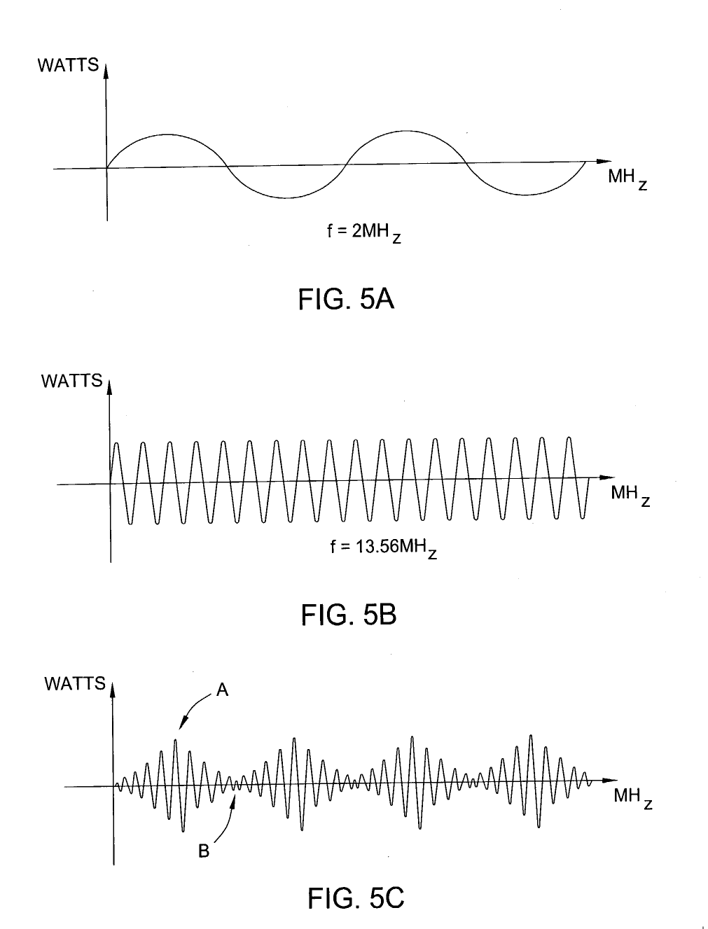

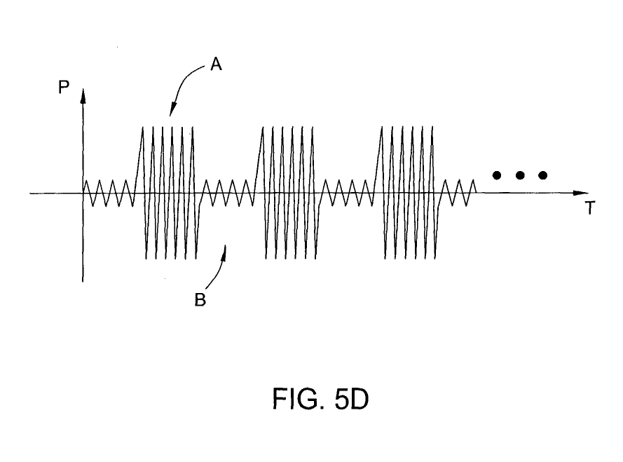

FIGS. 5A-5D depict graphs of exemplary RF waveforms used in the present invention. FIG. 5A depicts a 2 MHz biasing signal, FIG. 5B depicts a 13.56 MHz biasing signal, and FIG. 5C depicts a modulated biasing signal. In FIGS. 5A-5C, each waveform graph has a y-axis representing magnitude of power, and an x-axis representing frequency. In particular, FIG. 5C shows the resultant amplitude modulated continuous wave (CW) signal, where the 13.56 MHz RF signal is modulated by the 2 MHz RF signal.

FIG. 5D depicts a graph illustrating a modulated pulsed waveform. In this instance, a square wave is used as a modulating signal, which produces the modulated signal shown in FIG. 5D, where the amplitude of the modulated signal varies in strength as a function of the modulating waveform. The modulated pulsed waveform graph has a y-axis representing magnitude of power, and an x-axis representing time. Each pulse represents modulated power having a pulse peak of about +/−3000 W, and a duty cycle between about 10 to 90 percent. Note that FIG. 5D illustratively shows a 50% duty cycle, however, one skilled in the art will appreciate that the duty cycle may vary depending on the particular recipe used to form the features (e.g., deep trench). The controller 110 controls the pulsed power to the biasing element 120 based on the particular processing recipe requirements. The pulses are repeated during processing to emulate a modulated waveform. It is noted that only one biasing power source (e.g., 150 or 154) is necessary to provide the modulated pulsed waveform shown in FIG. 5D.

At the peak magnitudes (higher energy levels) of the modulated CW (and pulsed) signal (point A) components of the plasma (e.g., ions) are accelerated toward the wafer, as compared to when the magnitude of the modulated CW signal (and modulated pulsed signal) approaches lower energy levels (point B). Further, the ion energy increases because of the low and medium frequency used for the bias power, as well as modulates as the amplitude modulates. Although the modulation waveforms are shown and discussed in FIGS. 5A-5D as a sine wave and square wave, those skilled in the art will appreciate that other waveforms may also be modulated onto a carrier signal.

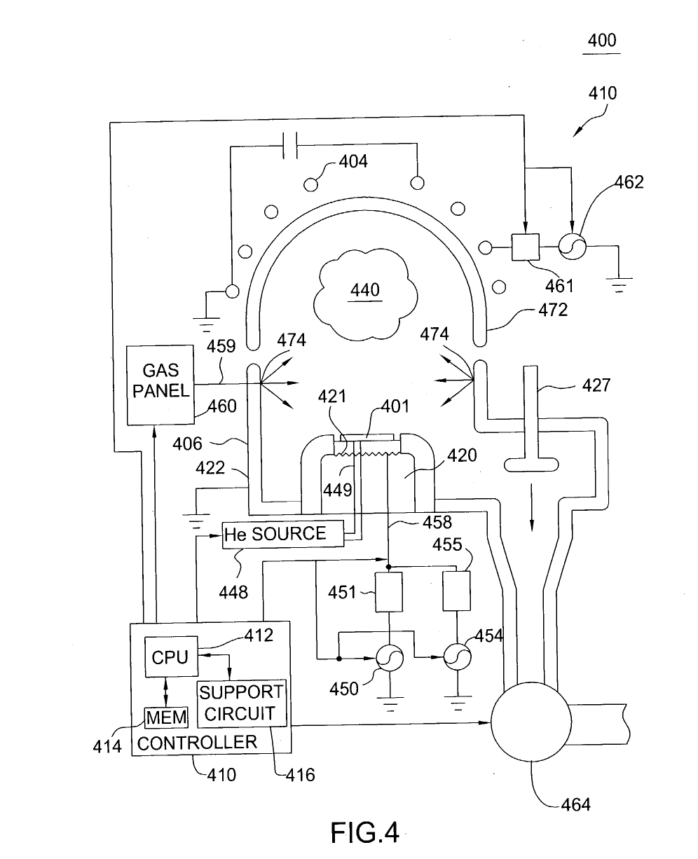

FIG. 4 depicts a cross-sectional view of a second embodiment of a dual frequency bias plasma chamber system 400. This second embodiment may also be used to practice the invention and is illustratively an inductively coupled plasma chamber reactor 400, such as a DPS-DT reactor, available from Applied Materials Inc., of Santa Clara, Calif. For a detailed description of the exemplary inductively coupled reactor 400, the reader is directed to U.S. Pat. Nos. 6,444,085, 6,454,898, 6444,084, and 6,270,617, which are incorporated herein by reference in their entirety. In general, any etch chamber having a plasma source element and a wafer bias element, where the wafer bias element is capable of being coupled to a modulated bias power may be utilized. That is, those skilled in the art will appreciate that other forms of etch chambers may be used to practice the invention, including chambers with remote plasma sources, microwave plasma chambers, electron cyclotron resonance (ECR) plasma chambers, among others.

The reactor 400 comprises a process chamber 406 having a wafer support pedestal 420 within a conductive body (wall) 422, and a controller 410. The wall 422 is supplied with a dome-shaped dielectric ceiling 472. Other modifications of the chamber 406 may have other types of ceilings, e.g., a flat ceiling. Typically, the wall 422 is coupled to an electrical ground. Above the ceiling 472 is disposed an inductive coil antenna 404. The inductive coil antenna 404 is coupled to a plasma power source 462, through a first matching network 461. The inductive coil antenna 404 serves as a plasma generating element, and is disposed as a spiral shaped helicoid around the dome ceiling 472. Alternatively, in instances where the invention is practiced in chamber 100 having a substantially flat ceiling 472, a stack or other forms of antennas 404 may be provided over the ceiling 472. The plasma power source 462 typically is capable of producing power between about 100 Watts and about 7500 Watts, at a frequency of about 2 MHz to about 180 MHz, and in one embodiment, at a frequency of about 2 MHz to 13.56 MHz.

The support pedestal (biasing element) 421, which is coupled, through a first matching network 451, to a first biasing power source 450, as well as a second matching network 455, to a second biasing power source 454. In one embodiment, the first and second biasing power supplies 150 and 154 are coupled to a chucking electrode (e.g., monopolar electrode), which is embedded in the support pedestal (chuck) and functions as the biasing element. Similar to the first embodiment shown in FIG. 1, the first biasing power supply 450 provides RF power in the range of about 10 Watts to 7500 Watts (W), and at a frequency in the range of about 100 KHz to 6 MHz. The second biasing power supply 454 provides RF power in the range of about 10 W to 7500 W, at a frequency in the range of about 10 MHz to 60 MHz relative the ground, and, for example, at a frequency of 13.56 MHz. As such, the signal from the first bias power supply 450 amplitude modulates the signal from the second bias power supply 454. For example, a 13.56 MHz signal from the second bias power supply 154 is amplitude modulated with a 2 MHz signal from the first biasing power supply 150, as discussed above with regard to method 300 of FIG. 3 and illustrated by the waveforms depicted in FIGS. 5A-5D.

In operation, a semiconductor wafer 401 is placed on the pedestal 420 and process gases are supplied from a gas panel 460 through gas entry ports (nozzles) 474 to provide a gaseous mixture in the processing region 440. The gaseous mixture is ignited into a plasma in the chamber 406 by applying power from the source 462 to the antenna 404. The pressure within the interior of the chamber 406 is controlled using a throttle valve 427 and a vacuum pump 464. The temperature of the chamber wall 422 is controlled using liquid-containing conduits (not shown) that run through the wall 422.

The temperature of the wafer 401 is controlled by stabilizing a temperature of the support pedestal 420. In one embodiment, helium gas from a source 448 is provided via a gas conduit 449 to channels formed by the back of the wafer 401 and grooves (not shown) on the pedestal surface. The helium gas is used to facilitate heat transfer between the pedestal 420 and the wafer 401.

To facilitate control of the chamber as described above, the controller 410 may be one of any form of general-purpose computer processor that can be used in an industrial setting for controlling various chambers and sub-processors. The controller 410 comprises a central processing unit (CPU) 412, a memory 414, and support circuits 416 for the CPU 412. The controller 410 facilitates control of the components of the DPS etch process chamber 400 in a similar manner as discussed for the controller 110 and chamber 106 of FIG. 1.

Accordingly, an apparatus for controlling a plasma in a chamber during wafer processing has been shown and discussed above. The apparatus comprises a biasing element disposed in the chamber and adapted to support a wafer, and a plasma generating element is disposed over the biasing element. A first power source is coupled to the plasma generating element, and a second power source is also coupled to the biasing element to provide a modulated signal to the biasing element.

It is noted that the teachings of the present invention have been shown and described in two exemplary etching chambers utilizing a source power supply 162 and 462 to control ion energy and ion bombardment on the wafers. However, the present invention is also applicable where no power (i.e., power (W) and frequency (Hz) both equal zero) is provided from a source power supply, such as in an eMAX chamber, which is available from Applied Materials Inc. of Santa Clara, Calif. In this instance, the chamber surface serves as an RF ground (anode) with respect to the biasing power supplies 150 and 154, and one of the biasing power supplies may be utilized to serve as both bias and source power supplies.

Although various embodiments that incorporate the teachings of the present invention have been shown and described in detail herein, those skilled in the art can readily devise many other varied embodiments that still incorporate these teachings.

What is claimed is:

1. Apparatus for controlling a plasma in a chamber during wafer processing, comprising:
a biasing element disposed in said chamber and adapted to support a wafer;
a plasma generating element disposed over said biasing element;
a first power source coupled to said plasma generating element; and
a second power source coupled to said biasing element that provides a modulated signal to said biasing element.

2. The apparatus of claim 1, wherein said biasing element comprises a substrate support pedestal.

3. The apparatus of claim 2, wherein said biasing element further comprises at least one chucking electrode disposed in said substrate support pedestal.

4. The apparatus of claim 2, wherein said biasing element further comprises a cooling plate formed in said substrate support pedestal.

5. The apparatus of claim 2, wherein said biasing element further comprises a pedestal base plate formed in said substrate support pedestal.

6. The apparatus of claim 1, wherein said plasma generating element further comprises a gas diffuser disposed over said chamber.

7. The apparatus of claim 1, wherein said plasma generating element further comprises coil antennas positioned over a lid, which is disposed over said chamber.

8. The apparatus of claim 1, wherein said first power source provides power in a range between about 0 Watts and about 7500 Watts, at a frequency in a range between about 0 MHz to about 180 MHz.

9. The apparatus of claim 1, wherein said second power source provides modulated pulsed waveforms.

10. The apparatus of claim 9, wherein said modulated pulsed waveforms have a voltage magnitude in a range of about 100 and 7500 volts, and a duty cycle between about 10 and 90 percent.

11. The apparatus of claim 1, wherein said second power source comprises:
an intermediate RF power source coupled to said biasing element; and
a low RF power source coupled to said biasing element.

12. The apparatus of claim 10, wherein:
said low RF power source provides a first RF power signal between about 10 Watts and about 7500 Watts at a frequency between 100 KHz and 6 MHz to said biasing element;
said intermediate RF power source provides a second RF power signal in a range between about 10 Watts and about 7500 Watts at a frequency between 10 MHz and 60 MHz to said biasing element; and
wherein said second RF power signal is modulated by said first RF power signal.

13. The apparatus of claim 12, wherein said first and second RF power signals have frequencies of 2 MHz and 13.56 MHz, respectively.

14. The apparatus of claim 12, wherein said first RF power signal is a waveform selected from the group comprising a sine wave and a square wave.

15. A method for selectively controlling a plasma in a processing chamber during wafer processing, comprising:
providing process gasses into said chamber over a wafer to be processed;
coupling high frequency RF power to a plasma generating element and igniting said process gases into said plasma;
coupling modulated RF power to a biasing element; and
performing said wafer processing according to a particular processing recipe.

16. The method of claim 15, wherein said coupling high frequency RF power step further comprises coupling source power between about 0 Watts and about 7500 Watts, at a frequency of about 0 MHz to about 180 MHz.

17. The method of claim 15, wherein said coupling modulated RF power further comprises:
coupling a first RF power signal in a range between about 10 Watts and about 7500 Watts at a frequency between 100 KHz and 6 MHz to said biasing element; and
coupling a second RF power signal in a range between about 10 Wafts and about 7500 Watts at a frequency between 10 MHz and 60 MHz to said biasing element; and
wherein said second RF power signal is modulated by said first RF power signal.

18. The method of claim 17, wherein said first and second RF power signals have frequencies of 2 MHz and 13.56 MHz, respectively.

19. The method of claim 18, wherein said first RF power signal comprises a sine wave.

20. The method of claim 18, wherein said first RF power signal comprises a square wave, said square wave modulated on said second RF power signal and producing a pulse-like signal.

21. The method of claim 20, wherein said pulse-like signal has a voltage magnitude in a range of about 100 and 7500 volts and a duty cycle between about 10 and 90 percent.

22. The method of claim 15, wherein said wafer processing comprises an etch process or a deposition process.

23. A method for plasma etching a trench in a semiconductor substrate disposed in a chamber, comprising:
providing process gases into the chamber and over the substrate to be etched;
coupling a high frequency RF power signal in a range of about 100 to 7500 Watts, at a frequency in a range of about 40 to 180 MHz, to a plasma generating element and igniting said process gases into a plasma;
coupling a modulated RF power signal in a range of about 10 to 7500 Watts, to a biasing element; and
performing said plasma etching on said substrate.

24. The method of claim 23 wherein the modulated RF power signal comprises a first RF signal in a range of about 10 to 7500 Watts, at a frequency in a range of about 2 KHz to 6 Mhz modulating a second RF signal in a range of about 10 to 7500 Watts, at a frequency in a range of about 10 MHz to 60 MHz.

25. The method of claim 24 wherein the providing process gases step further comprises:
providing between 5 to 2000 sccm of at least one process gas selected from the group consisting of CF₄, Ar, C₄F₈, C₄F₆, C₈F₄, CHF₃, Cl₂, HBr, NF₃, N₂, He, O₂; and
maintaining a pressure in a range of about 2 to 1000 mTorr.
